(19) United States
(12) Patent Application Publication
(10) Pub. No.: US 2022/0195111 A1
(43) Pub. Date: Jun. 23, 2022

(54) CONDUCTIVE POLYMER, CAPACITOR AND PREPARATION METHOD THEREOF

(71) Applicant: SHENZHEN CAPCHEM TECHNOLOGY CO., LTD., Shenzhen, Guangdong (CN)

(72) Inventors: Dacheng Zhao, Shenzhen, Guangdong (CN); Minxiang Yan, Shenzhen, Guangdong (CN)

(21) Appl. No.: 17/603,940

(22) PCT Filed: May 8, 2020
(86) PCT No.: PCT/CN2020/089098

§ 371 Date: Oct. 14, 2021

(30) Foreign Application Priority Data
May 9, 2019 (CN) 201910386211.6

(51) Int. Cl. C08G 61/12; C09D 165/00; H01G 9/025; H01G 9/00

(52) U.S. Cl. CPC C08G 61/126; C09D 165/00; H01G 9/025; H01G 9/0036; C08G 2261/514; C08G 2261/3223; C08G 2261/145; C08G 2261/1426; C08G 2261/11

(57) ABSTRACT

The application provides a conductive polymer, comprising a segment obtained by polymerizing a polymer monomer, wherein the polymer monomer comprises a compound represented by Formula I:

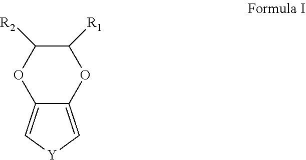

wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group. Meanwhile, the application discloses a capacitor comprising the conductive polymer and a preparation method thereof. The conductive polymer provided by the application has a lower ESR and stable electrical performance.

### TECHNICAL FIELD

The application belongs to the technical field of capacitors, and particularly relates to a conductive polymer, a capacitor and a preparation method thereof.

### BACKGROUND

Compared with regular electrolytic capacitors, solid electrolytic capacitors adopts solid conductive materials with high conductivity and good thermal stability as electrolyte, which not only has all the properties of regular electrolytic capacitors, but also has the advantages of good reliability, long service life, low impedance at high frequency, and are able to overcome the disadvantages of liquid electrolytic capacitors such as leakage and short service life. The domestic electronic information industry is developing rapidly. The development trend in recent years shows that solid electrolytic capacitors would gradually replace regular low-voltage electrolytic capacitors, and would become one of the pillar products of electronic information industry in the 21st century.

With the increasing requirements for the performances of solid electrolytic capacitors, it has become a common goal of researchers to further improve the conductivity of conductive polymers and thus reduce ESR of capacitors. Doping is an effective way to improve the conductivity of polymers. High polymer materials with conjugated double bonds can be oxidized or reduced by adding dopants to obtain better electrochemical activity. By doping, the energy band gap and the migration resistance of free charge can be reduced, so that the conductivity of conjugated polymer can be significantly improved by a few or a dozen orders of magnitude. Because of the conjugated structure of polymer, π-electrons have high electron mobility and high degree of electron delocalization. At present, dopants (such as iodine and ferric chloride) are usually introduced into polymer systems. Because of its low electronic dissociability, it can lose or partially lose electrons and be oxidized, resulting in P-type doping. And because of its good electron affinity, it can obtain some or all of the electrons and be reduced, resulting in N-type doping, which leads to the improvement of conductivity of the polymer. For example, in the prior art, most conductive polymer materials are doped with dopants such as polystyrene sulfonic acid or p-toluenesulfonic acid, so as to improve the conductivity.

At present, the performance of capacitors is usually improved by adding external dopants. However, there are some problems such as poor compatibility and poor dispersion between dopants and conjugated polymers, which hinder the further improvement of conductivity. Moreover, it is particularly important that after the polymer dispersion doped with commonly used dopants is used in solid electrolytic capacitors, the problem of dedoping often occurs in the process of charge and discharge, which makes the capacity extraction rate of solid electrolytic capacitors decrease rapidly, and ESR increases rapidly, leading to rapid deterioration and failure of solid electrolytic capacitors.

### SUMMARY

The application provides a conductive polymer, a capacitor and a preparation method thereof, aiming at the poor conductivity of the conductive polymer dispersion in the existing solid capacitor and the problem of dedoping in the existing way of adding dopant into electrolyte.

The technical solutions adopted by the application to solve the technical problems are as follows.

In an aspect, the application provides a conductive polymer, including a segment obtained by polymerizing a polymer monomer, wherein the polymer monomer includes a compound represented by Formula I:

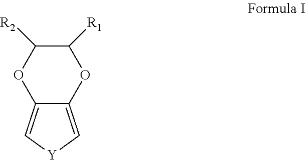

wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group.

Optionally, the alkyl group is selected from a substituted or unsubstituted linear or branched C1-C18 alkyl group, the cycloalkyl group is selected from a substituted or unsubstituted C5-C12 cycloalkyl group, the aryl group is selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

In another aspect, the present application provides a capacitor, including a conductive polymer as described above.

In another aspect, the application provides a preparation method for a capacitor, including the following steps:

obtaining a monomer solution, wherein the monomer solution includes a compound represented by Formula I:

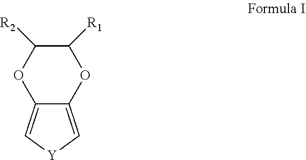

wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group;

impregnating a capacitor element in the monomer solution, then the capacitor element is taken out, dried, impregnated in an oxidizer solution, receives polymerization reaction, encapsulated and assembled to obtain a capacitor.

Optionally, the alkyl group is selected from a substituted or unsubstituted linear or branched C1-C18 alkyl group, the cycloalkyl group is selected from a substituted or unsubstituted C5-C12 cycloalkyl group, the aryl group is selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

Optionally, the oxidizer solution is an iron p-toluenesulphonate in ethanol or n-butanol.

Optionally, a drying temperature is 50° C.˜150° C.

Optionally, for the polymerization reaction, its temperature is first stepped up and then stepped down at a range of 30° C.˜200° C., its humidity is stepped down to 0% in a range of 0˜60%, and reaction time is 5˜20 h.

Optionally, the step of “impregnated in an oxidizer solution” is carried out in vacuum.

Optionally, a vacuum degree of vacuum impregnation is −0.05˜−0.10 MPa.

According to the conductive polymer provided by the application, carboxyl group, sulfonic acid group or phosphate group is self-doped at at least one of 2′ and 3′ positions of 3,4-ethylenedioxythiophene by chemical bonding to obtain a polymer monomer. And compared with conventional electrolyte, the conductive polymer obtained by in-situ polymerization of the polymer monomer can effectively improve conductivity of the conductive polymer. It conducts electricity through free electron movement, which can effectively improve the efficiency of charge migration at interface, thus improving the conductivity. And because carboxyl group, sulfonic acid group or phosphate group in the conductive polymer are introduced by chemical bond self-doping, the conductive polymer has strong doping stability, and the chain segment combination is firmer. The solid electrolytic capacitor prepared by the polymer dispersion can effectively improve the performance of charging-discharging cycles, thus avoiding the problems of rapid decrease of the capacity extraction rate and rapid increase of ESR of the solid electrolytic capacitor caused by dedoping.

### DETAILED DESCRIPTION OF DISCLOSED EMBODIMENTS

In order to make the technical problems solved by the present application, technical solutions and beneficial effects clearer, the present application will be further described in detail with reference to the following embodiments. It should be understood that the specific embodiments described herein are only used to illustrate the present application, not intended to limit the present application.

An embodiment of the present application provides a conductive polymer, including a segment obtained by polymerizing a polymer monomer, wherein the polymer monomer includes a compound represented by Formula I:

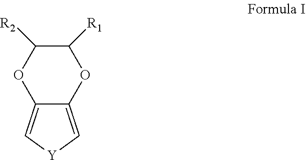

wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group.

The conductivity of polyelectrolyte can be improved to a certain extent because of carboxyl group, sulfonic acid group and phosphate group contained in R₁ and R₂, and the polyelectrolyte has a low ESR value. And because carboxyl group, sulfonic acid group or phosphate group in the conductive polymer are introduced by chemical bond self-doping, the conductive polymer has strong doping stability, and the chain segment combination is firmer. The solid electrolytic capacitor prepared by the polymer dispersion can effectively improve the performance of charging-discharging cycles, thus avoiding the problems of rapid decrease of the capacity extraction rate and rapid increase of ESR of the solid electrolytic capacitor caused by dedoping.

It should be noted that in the above description, the optionally substituted alkyl group includes an alkyl group whose hydrogen is substituted by one or more of a carboxyl group, sulfonic acid group and phosphate group; the optionally substituted cycloalkyl includes a cycloalkyl group whose hydrogen is substituted by one or more of a carboxyl group, sulfonic acid group and phosphate group; the optionally substituted aryl includes an aryl group whose hydrogen is substituted by one or more of a carboxyl group, sulfonic acid group and phosphate group; the optionally substituted aralkyl includes an aralkyl whose hydrogen is substituted by one or more of a carboxyl group, sulfonic acid group and phosphate group; and the optionally substituted alkoxy includes alkoxy whose hydrogen is substituted by one or more of a carboxyl group, sulfonic acid group and phosphate group.

In some embodiments, the alkyl group is selected from a substituted or unsubstituted linear or branched C1-C18 alkyl group, the cycloalkyl group is selected from a substituted or unsubstituted C5-C12 cycloalkyl group, the aryl group is selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

Another embodiment of the present application provides a capacitor, including the conductive polymer as described above.

The capacitor is an aluminum electrolytic solid capacitor.

Another embodiment of the present application provides a preparation method for a capacitor, including the following steps:

obtaining a monomer solution, wherein the monomer solution includes a compound represented by Formula I:

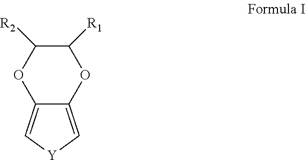

wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group;

impregnating a capacitor element in the monomer solution, then the capacitor element is taken out, dried, impregnated in an oxidizer solution, receives polymerization reaction, encapsulated and assembled to obtain a capacitor.

The capacitor element includes a positive electrode, a separator and a negative electrode which are laminated and wound together.

It should be noted that in the above description, the optionally substituted alkyl group includes an alkyl group whose hydrogen is substituted by one or more of a carboxyl group, sulfonic acid group and phosphate group; the optionally substituted cycloalkyl includes a cycloalkyl group whose hydrogen is substituted by one or more of a carboxyl group, sulfonic acid group and phosphate group; the optionally substituted aryl includes an aryl group whose hydrogen is substituted by one or more of a carboxyl group, sulfonic acid group and phosphate group; the optionally substituted aralkyl includes an aralkyl whose hydrogen is substituted by one or more of a carboxyl group, sulfonic acid group and phosphate group; and the optionally substituted alkoxy includes alkoxy whose hydrogen is substituted by one or more of a carboxyl group, sulfonic acid group and phosphate group.

In some embodiments, the alkyl group is selected from a substituted or unsubstituted linear or branched C1-C18 alkyl group, the cycloalkyl group is selected from a substituted or unsubstituted C5-C12 cycloalkyl group, the aryl group is each independently selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

In some embodiments, the mass percentage of the polymer monomer in the monomer solution is 20%˜40%.

The solvent in the monomer solution may be an existing organic solvent, such as ethanol.

In some embodiments, the mass percentage of oxidizer in the oxidizer solution is 40%˜65%.

In some embodiments, the oxidizer solution is an iron p-toluenesulphonate in ethanol or n-butanol.

The oxidizer solution can reduce the polymerization reaction rate, appropriately prolong the polymerization reaction time, facilitate the full impregnation of the solid electrolytic capacitor element, improve the conductivity and crystallinity of the conductive polymer, other impurities harmful to the electrochemical performance of the conductive polymer would not remain, and is simple and convenient to operate. And because of the low boiling points of ethanol or n-butanol solutions, they would volatilize continuously and not remain in the reaction process, thus obtaining conductive polymer with excellent electrochemical performance.

In some embodiments, the drying temperature is 50° C.˜150° C.

In some embodiments, for the polymerization reaction, its temperature is first stepped up and then stepped down at a range of 30° C.˜200° C., its humidity is stepped down to 0% in a range of 0˜60%, and reaction time is 5˜20 h.

In some preferred embodiments, the drying temperature is 60° C.˜100° C., the temperature of the polymerization reaction is first stepped up and then stepped down at a range of 50° C.˜130° C., the humidity is stepped down to 0% in a range of 0˜40%, and reaction time is 7˜13 h.

Through stepwise increase, decrease of temperature and decrease of humidity, the stable progress of polymerization reaction can be effectively promoted and volatile solvents and moisture therein can be removed.

In some embodiments, the step of “impregnated in an oxidizer solution” is carried out in vacuum.

In a more preferred embodiment, the vacuum degree of vacuum impregnation is −0.05˜−0.10 MPa.

Through the vacuum impregnation, the oxidizer solution can be promoted to penetrate into the capacitor element, so that the oxidizer and polymer monomer can be fully mixed, the following polymerization reaction can be promoted, and the air mixed in the impregnation process can be avoided at the same time.

The application will be further illustrated with the following embodiments.

### Embodiment 1

The embodiment is used for illustrating the conductive polymer, capacitor and preparation method thereof disclosed by the application, which includes the following steps:

S1. Use 3,4-ethylenedioxythiophene-2′-methanesulfonic acid as a polymer monomer and ethanol as a solvent to prepare a 25% monomer solution; impregnate the monomer solution with a capacitor element for 2 minutes; take out the capacitor element, dry in an oven at 80° C. for 30 minutes, and then cool to room temperature.

S2. After the treatment in the above step, impregnate the capacitor element in 55% iron p-toluenesulphonate in ethanol oxidizer solution in vacuum, with a vacuum degree of −0.085 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 50° C. and the humidity of 30%; then adjust temperature to 70° C., humidity to 20%, and react for 2 h; adjust temperature to 150° C., humidity to 0%, and react for 1 h; adjust temperature to 110° C., humidity to 0%, and react for 3 h.

S4. After the polymerization reaction is finished, the capacitor element is encapsulated and assembled into a solid electrolytic capacitor.

### Embodiment 2

The embodiment is used for illustrating the conductive polymer, capacitor and preparation method thereof disclosed by the application, which includes the following steps:

S1. Use 3,4-ethylenedioxythiophene-2′,3′-bismethanesulfonic acid as a polymer monomer and ethanol as a solvent to prepare a 27% monomer solution; impregnate the monomer solution with a capacitor element for 2 minutes; take out the capacitor element, dry in an oven at 90° C. for 30 minutes, and then cool to room temperature.

S2. After the treatment in the above step, impregnate the capacitor element in 60% iron p-toluenesulphonate in ethanol oxidizer solution in vacuum, with a vacuum degree of −0.09 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 40° C. and the humidity of 40%; then adjust temperature to 60° C., humidity to 20%, and react for 2 h; adjust temperature to 130° C., humidity to 0%, and react for 1 h; adjust temperature to 105° C., humidity to 0%, and react for 4 h.

S4. After the polymerization reaction is finished, the capacitor element is encapsulated and assembled into a solid electrolytic capacitor.

### Embodiment 3

The embodiment is used for illustrating the conductive polymer, capacitor and preparation method thereof disclosed by the application, which includes the following steps:

S1. Use 3,4-ethylenedioxythiophene-2′-acetic acid as a polymer monomer and ethanol as a solvent to prepare a 26% monomer solution; impregnate the monomer solution with a capacitor element for 2 minutes; take out the capacitor element, dry in an oven at 100° C. for 30 minutes, and then cool to room temperature.

S2. After the treatment in the above step, impregnate the capacitor element in 50% iron p-toluenesulphonate in n-butanol oxidizer solution in vacuum, with a vacuum degree of ˜0.085 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 50° C. and the humidity of 35%; then adjust temperature to 60° C., humidity to 25%, and react for 3 h; adjust temperature to 140° C., humidity to 0%, and react for 2 h; adjust temperature to 105° C., humidity to 0%, and react for 4 h.

S4. After the polymerization reaction is finished, the capacitor element is encapsulated and assembled into a solid electrolytic capacitor.

### Embodiment 4

The embodiment is used for illustrating the conductive polymer, capacitor and preparation method thereof disclosed by the application, which includes the following steps:

S1. Use 3,4-ethylenedioxythiophene-2′,3′-succinic acid as a polymer monomer and ethanol as a solvent to prepare a 26% monomer solution; impregnate the monomer solution with a capacitor element for 2 minutes; take out the capacitor element, dry in an oven at 130° C. for 30 minutes, and then cool to room temperature.

S2. After the treatment in the above step, impregnate the capacitor element in 55% iron p-toluenesulphonate in n-butanol oxidizer solution in vacuum, with a vacuum degree of −0.09 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 60° C. and the humidity of 30%; then adjust temperature to 100° C., humidity to 0%, and react for 2 h; adjust temperature to 150° C., humidity to 0%, and react for 2 h; adjust temperature to 110° C., humidity to 0%, and react for 3 h.

S4. After the polymerization reaction is finished, the capacitor element is encapsulated and assembled into a solid electrolytic capacitor.

### Embodiment 5

The embodiment is used for illustrating the conductive polymer, capacitor and preparation method thereof disclosed by the application, which includes the following steps:

S1. Use 3,4-ethylenedioxythiophene-2′-methoxymethanesulfonic acid as a polymer monomer and ethanol as a solvent to prepare a 25% monomer solution; impregnate the monomer solution with a capacitor element for 2 minutes; take out the capacitor element, dry in an oven at 150° C. for 30 minutes, and then cool to room temperature.

S2. After the treatment in the above step, impregnate the capacitor element in 55% iron p-toluenesulphonate in ethanol oxidizer solution in vacuum, with a vacuum degree of ˜0.085 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 1 h at the temperature of 40° C. and the humidity of 40%; then adjust temperature to 80° C., humidity to 20%, and react for 2 h; adjust temperature to 130° C., humidity to 0%, and react for 2 h; adjust temperature to 100° C., humidity to 0%, and react for 3 h.

S4. After the polymerization reaction is finished, the capacitor element is encapsulated and assembled into a solid electrolytic capacitor.

### Embodiment 6

The embodiment is used for illustrating the conductive polymer, capacitor and preparation method thereof disclosed by the application, which includes the following steps:

S1. Use 3,4-ethylenedioxythiophene-2′,3′-dimethoxymethanesulfonic acid as a polymer monomer and ethanol as a solvent to prepare a 28% monomer solution; impregnate the monomer solution with a capacitor element for 2 minutes; take out the capacitor element, dry in an oven at 120° C. for 30 minutes, and then cool to room temperature.

S2. After the treatment in the above step, impregnate the capacitor element in 50% iron p-toluenesulphonate in n-butanol oxidizer solution in vacuum, with a vacuum degree of −0.09 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 50° C. and the humidity of 30%; then adjust temperature to 70° C., humidity to 20%, and react for 2 h; adjust temperature to 140° C., humidity to 0%, and react for 2 h; adjust temperature to 105° C., humidity to 0%, and react for 3 h.

S4. After the polymerization reaction is finished, the capacitor element is encapsulated and assembled into a solid electrolytic capacitor.

### Embodiment 7

The embodiment is used for illustrating the conductive polymer, capacitor and preparation method thereof disclosed by the application, which includes the following steps:

S1. Use 3,4-ethylenedioxythiophene-2′-methylphosphoric acid as a polymer monomer and ethanol as a solvent to prepare a 27% monomer solution; impregnate the monomer solution with a capacitor element for 2 minutes; take out the capacitor element, dry in an oven at 120° C. for 30 minutes, and then cool to room temperature.

S2. After the treatment in the above step, impregnate the capacitor element in 60% iron p-toluenesulphonate in ethanol oxidizer solution in vacuum, with a vacuum degree of −0.08 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 60° C. and the humidity of 30%; then adjust temperature to 90° C., humidity to 20%, and react for 2 h; adjust temperature to 150° C., humidity to 0%, and react for 1 h; adjust temperature to 110° C., humidity to 0%, and react for 3 h.

S4. After the polymerization reaction is finished, the capacitor element is encapsulated and assembled into a solid electrolytic capacitor.

### Comparative Example 1

The comparative example is used for comparing and illustrating the conductive polymer, capacitor and preparation method thereof disclosed by the application, which includes the following steps:

S1. Use 3,4-ethylenedioxythiophene as a polymer monomer and ethanol as a solvent to prepare a 27% monomer solution; impregnate the monomer solution with a capacitor element for 2 minutes; take out the capacitor element, dry in an oven at 100° C. for 30 minutes, and then cool to room temperature.

S2. After the treatment in the above step, impregnate the capacitor element in 55% iron p-toluenesulphonate in n-butanol oxidizer solution in vacuum, with a vacuum degree of −0.09 MPa; slowly put the capacitor element into the oxidizer solution, and keep the temperature at 20˜25° C. for 5 min.

S3. After the impregnation is finished, remove the capacitor element, put the capacitor element into a constant temperature and humidity box for polymerization reaction, and allow it to react for 2 h at the temperature of 50° C. and the humidity of 30%; then adjust temperature to 80° C., humidity to 20%, and react for 2 h; adjust temperature to 150° C., humidity to 0%, and react for 2 h; adjust temperature to 105° C., humidity to 0%, and react for 3 h.

S4. After the polymerization reaction is finished, the capacitor element is encapsulated and assembled into a solid electrolytic capacitor.

### Performance Test

The following performance tests were conducted on the solid electrolytic capacitors prepared in Embodiments 1-7 and Comparative Example 1:

Automatic electronic parts analyzer was adopted to test the electrostatic capacity, loss value and equivalent series resistance of capacitors. The test method may a conventional measurement of solid electrolytic capacitors, which would not be described in detail here.

Then, under the condition of 1.15 times of rated voltage, the solid electrolytic capacitors were charged for 3 seconds and then discharged for 3 seconds. After 1000 times of the charge-discharge cycle, the electrostatic capacity, loss value and equivalent series resistance of the solid electrolytic capacitors were tested again.

The test results are shown in Table 1.

The test results are filled in Table 1.

TABLE 1
Performance test results of solid aluminum electrolytic capacitor
(16V470 μF core package)

| | Before charge | | | | | | |
|---|---|---|---|---|---|---|---|
| | and discharge | | | After charge and discharge | | | |
| Embodiment | Cap(μF) | DF(%) | ESR(mΩ) | Cap(μF) | DF(%) | ESR(mΩ) | ΔC(%) |
| Embodiment 1 | 468 | 2.1 | 8.2 | 463 | 2.2 | 9.0 | −1.1 |
| Embodiment 2 | 472 | 2.0 | 7.6 | 470 | 2.2 | 7.9 | −0.4 |
| Embodiment 3 | 462 | 2.3 | 8.3 | 458 | 2.4 | 8.9 | −0.9 |
| Embodiment 4 | 460 | 2.2 | 7.7 | 455 | 2.3 | 8.3 | −1.1 |
| Embodiment 5 | 463 | 2.3 | 8.1 | 460 | 2.4 | 9.1 | −0.6 |
| Embodiment 6 | 459 | 2.4 | 8.4 | 458 | 2.6 | 9.5 | −0.2 |
| Embodiment 7 | 465 | 2.2 | 8.3 | 463 | 2.3 | 9.4 | −0.4 |
| Comparative | 466 | 2.3 | 9.3 | 432 | 2.5 | 13.2 | −7.3 |
| example 1 | | | | | | | |

It can be seen from the test results in Table 1 that the solid electrolytic capacitor prepared by the conductive polymer provided by the present application has a low ESR, and the capacity fade is low after the charge-discharge cycle, and the maximum capacity fade is only −1.1%. However, in Comparative example 1, the charge-discharge cycle, the capacity fade of the solid electrolytic capacitor prepared by conventional monomer is relatively large (−7.3%), which indicates that the conductive polymer of the present application basically does not undergo dedoping after the cycle of charge-discharge, and the stability of the conductive polymer is excellent, thus ensuring the performance stability of the solid electrolytic capacitor and greatly prolonging the service life of the solid electrolytic capacitor.

The above are only preferred embodiments of the present application, not intended to limit the present application. Any modifications, equivalent substitutions and improvements made within the spirit and principles of the present application shall be included in the scope of protection of the present application.

1. A conductive polymer, comprising a segment obtained by polymerizing a polymer monomer, wherein the polymer monomer comprises a compound represented by Formula I: 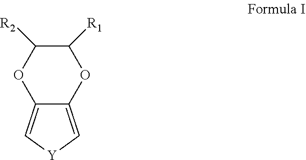
wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group.

2. The conductive polymer of claim 1, wherein the alkyl group is selected from a substituted or unsubstituted linear or branched C1-C18 alkyl group, the cycloalkyl group is selected from a substituted or unsubstituted C5-C12 cycloalkyl group, the aryl group is selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

3. A capacitor, comprising the conductive polymer of claim 1.

4. A preparation method for a capacitor, comprising the following steps:
obtaining a monomer solution, wherein the monomer solution comprises a compound represented by Formula I: 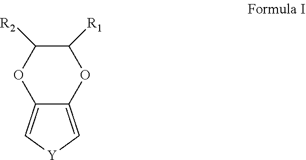
wherein Y is selected from one of NH and S; R₁ and R₂ are independently selected from H, an optionally substituted linear or branched alkyl group, optionally substituted cycloalkyl group, optionally substituted aryl group, optionally substituted aralkyl group, optionally substituted alkoxy group or hydroxyl group, or an organic group containing at least one of a carboxyl group, sulfonic acid group and phosphate group, and at least one of R₁ and R₂ is an organic group containing at least one of carboxyl group, sulfonic acid group and phosphate group;
impregnating a capacitor element in the monomer solution, then the capacitor element is taken out, dried, impregnated in an oxidizer solution, receives polymerization reaction, encapsulated and assembled to obtain a capacitor.

5. The preparation method for a capacitor of claim 4, wherein the alkyl group is selected from a substituted or unsubstituted linear or branched C1-C18 alkyl group, the cycloalkyl group is selected from a substituted or unsubstituted C5-C12 cycloalkyl group, the aryl group is selected from a substituted or unsubstituted C6-C14 aryl group, the aralkyl group is selected from a substituted or unsubstituted C7-C18 aralkyl group, and the alkoxy group is selected from a substituted or unsubstituted C1-C18 alkoxy group.

6. The preparation method for a capacitor of claim 4, wherein the oxidizer solution is an iron p-toluenesulphonate in ethanol or n-butanol.

7. The preparation method for a capacitor of claim 4, wherein a drying temperature is 50° C.˜150° C.

8. The preparation method for a capacitor of claim 4, wherein for the polymerization reaction, its temperature is first stepped up and then stepped down at a range of 30° C.˜200° C., its humidity is stepped down to 0% in a range of 0˜60%, and reaction time is 5˜20 h.

9. The preparation method for a capacitor of claim 4, wherein the step of “impregnated in an oxidizer solution” is carried out in vacuum.

10. The preparation method for a capacitor of claim 9, wherein a vacuum degree of vacuum impregnation is −0.05˜−0.10 MPa.

11. A capacitor, comprising the conductive polymer of claim 2.
